(19) United States
(12) Patent Application Publication
(10) Pub. No.: US 2008/0106922 A1
(43) Pub. Date: May 8, 2008

(54) SEMICONDUCTOR MEMORY DEVICE AND LAYOUT STRUCTURE OF WORD LINE CONTACTS

(76) Inventors: Joon-Min Park, Seoul (KR); Byung-Gil Choi, Yongin-si (KR); Du-Eung Kim, Yongin-si (KR); Beak-Hyung Cho, Hwaseong-si (KR)

Correspondence Address: F. CHAU & ASSOCIATES, LLC, 130 WOODBURY ROAD, WOODBURY, NY, 11797, US

(21) Appl. No.: 11/735,635

(22) Filed: Apr. 16, 2007

(30) Foreign Application Priority Data
Nov. 2, 2006 (KR) 10-2006-0107532

(51) Int. Cl. G11C 5/06; G11C 11/00

(52) U.S. Cl. 365/72; 365/148; 365/63

(57) ABSTRACT

A semiconductor memory device and a layout structure of word line contacts, in which the semiconductor memory device includes an active region, a plurality of memory cells, and word line contacts. The active region is disposed in a first direction as a length direction on a semiconductor substrate and is used as a word line. The plurality of memory cells are disposed in the first direction on the active region and are each constructed of one variable resistance device and one diode device. In the word line contacts, at least one each is disposed between respective units, wherein each unit is constructed of predetermined numbers of memory cells on the active region. A bridge effect, such as a short-circuit between adjacent word lines, can be prevented or substantially reduced.

This U.S. nonprovisional patent application claims priority under 35 U.S.C. §119 of Korean Patent Application 10-2006-0107532 filed on Nov. 2, 2006, the entire contents of which are hereby incorporated by reference.

### TECHNICAL FIELD

The present disclosure relates to semiconductor memory devices and, more particularly, to a semiconductor memory device and a layout structure of word line contacts, which are capable of preventing or substantially reducing a bridge effect, such as a short-circuit in the word line contacts.

### DISCUSSION OF RELATED ART

Next-generation memory devices, which are nonvolatile and do not require a refresh operation, have been researched in view of the trends of high capacity and low power consumption for such devices. In the next-generation memory devices currently being researched there are a PRAM (Phase change Random Access Memory) containing phase change material, an RRAM (Resistance Random Access Memory) containing material having properties of variable resistance, and an MRAM (Magnetic Random Access Memory) containing ferromagnetic material.

In the next generation memory devices the PRAM employs phase change material as a storage medium. Typically, the phase change material is a material such as chalcogenide, in which phase is changed according to a temperature change, which results in a change of resistance. In the phase change material, material such as GeₓSb_{y}Te_{z} (hereinafter, referred to as ‘GST’) is used, the GST being an alloy of Ge (germanium), Sb (antimony) and Te (tellurium).

The phase change material can be advantageously used for semiconductor memory devices according to properties of the material being rapidly changeable into an amorphous state or crystalline state.

The phase change material has a high resistance in the amorphous state and has a low resistance in the crystalline state, thus, the amorphous state may be defined as a reset state RESET or logic ‘1’, and the crystalline state for the phase change material may be defined as a set state SET or logic ‘0’, or vice versa, in its application to the semiconductor memory devices.

Memory cells constituting the PRAM may be classified into a transistor structure and a diode structure. The transistor structure indicates a memory cell structure in which the phase change material is coupled in series to an access transistor, and the diode structure indicates a memory cell structure in which the phase change material is coupled in series to a diode.

As compared with the PRAM employing the transistor structure, the PRAM employing the diode structure has advantages of allowing write current, which exponentially increases according to an applied voltage, to flow therein, as well as deviating from a limitation for the transistor size and so of having a flexibility in a reduction of memory cell and overall chip size. Thus, a use of the PRAM employing a memory cell having a diode structure is expected to increase in semiconductor memory devices requiring high integration, high speed, and low power consumption.

FIG. 1 illustrates a memory cell having a diode structure for general use as a PRAM.

Referring to FIG. 1, a memory cell 50 in the PRAM is constructed of one diode D and one variable resistance device R. The variable resistance device R is formed of the phase change material described above.

The diode D constituting the memory cell 50 is coupled between a word line WL and the variable resistance device R, with a cathode terminal thereof being coupled to the word line WL and an anode terminal being coupled to one end of the variable resistance device R. Another end of the variable resistance device R is coupled to a bit line BL.

In the semiconductor memory device employing a memory cell of the diode structure described above, the variable resistance device R is provided as a data storage element, and a write operation using a reversible characteristic of the variable resistance device R is performed according to a magnitude of current and voltage source applied to the memory cell through the bit line BL. In other words, in performing the write operation to an optional memory cell 50, current is supplied through the bit line BL and the word line WL is transited to a low level or ground level, thus, a forward bias is applied to the diode D and a current path from the bit line BL to the word line WL is formed. At this time, a phase change is generated in the variable resistance device R coupled to the anode terminal of the diode D, and so it becomes a ‘set’ state of a low resistance or a ‘reset’ state of a high resistance.

In a read operation, data may be classified according to the amount of current flowing through the memory cell and according to the state of the memory cell, that is, the ‘set’ or ‘reset’ state. When the variable resistance device R within the memory cell has a ‘reset’ state, the memory cell has a high resistance value and so a relatively small quantity of current flows from a constant level of the bit line BL. On the other hand, when the memory cell has a ‘set’ state, the memory cell has a low resistance value and so a relatively large amount of current flows.

In a PRAM employing a memory cell having a diode device as described above, an active region coupled to the diode device D is used as the word line WL. The active region has a relatively large resistance, however, so a word line strapping line having relatively less resistance may be provided over the active region so as to be used in place of the word line WL. The word line strapping line is called a local word line LWL, or sub word line SWL, in a diagram of a general equivalent circuit. The active region and the word line strapping line are coupled through word line contacts.

It has currently been under discussion how to dispose the word line contacts, so as to be advantageous to high integration and efficient operation of a semiconductor memory device.

### SUMMARY OF THE INVENTION

Exemplary embodiments of the invention provide a semiconductor memory device and a layout structure of word line contacts. A bridge effect, such as a short-circuit of a word line contact, can be prevented or substantially reduced. The semiconductor memory device and the layout structure of the word line contacts may be advantageous to a high integration.

According to exemplary embodiments of the present invention, a semiconductor memory device includes an active region disposed in a first direction as a length direction on a semiconductor substrate, the active region being used as a word line; a plurality of memory cells disposed in the first direction on the active region, each of the plurality of memory cells having one variable resistance device and one diode device; and word line contacts, of which at least one each is disposed between respective units, in which one unit is constructed of predetermined numbers of memory cells on the active region.

The word line contacts may be electrically coupled with word line strapping lines disposed in the first direction as a length direction on the memory cells. The word line contacts disposed on the active region may be disposed so as not to be adjacent in a second direction to word line contacts that are disposed on active regions adjacent in the second direction, the second direction being intersected with the first direction.

Word line contacts disposed on the active region adjacent in the second direction to one word line contact disposed on the active region may be disposed on the active region adjacent to a position passing in the first direction by at least one memory cell region from a position adjacent die one word line contact.

A cathode region of the diode device constituting the memory cell may be coupled to the active region, and an anode region of the diode device may he coupled to the variable resistance device. At least one each of the word line contacts may be disposed in each unit, in which one unit is constructed of eight or four successive memory cells in the first direction.

The semiconductor memory device may be a PRAM in which the variable resistance device is formed of phase change material GST, or it may be an RRAM in which the variable resistance device is formed of a transition metal oxide.

According to exemplary embodiments of the present invention, in disposing word line contacts for electrically connecting an active region to a word line strapping line, on the active region on which memory cells are disposed and which is disposed in a first direction as a length direction and which is used as a word line; a layout structure of the word line contacts is characterized in that at least one each of the word line contacts is disposed on one active region every predetermined numbers of memory cells, and the word line contacts are disposed so as not to be adjacent in a second direction to word line contacts disposed on active regions that are adjacent in the second direction, the second direction being intersected with the first direction.

Word line contacts disposed on an active region adjacent in the second direction to one word line contact disposed on the active region may be disposed on the active region adjacent to a position passing in the first direction by at least one memory cell region from a position adjacent to the one word line contact.

The memory cell may include one variable resistance device and one diode device. A cathode region of the diode device constituting the memory cell may be coupled to the active region, and an anode region thereof may be coupled to the variable resistance device disposed on the diode device. In the word line contacts at least one each may be disposed in each unit, wherein one unit is constructed of eight or four memory cells.

The inventive configuration described above is advantageous to high integration and a bridge effect, such as short-circuit in word line contacts, can be prevented or substantially reduced.

### BRIEF DESCRIPTION OF THE DRAWINGS

Exemplary embodiments of the present invention will be understood in more detail from the following descriptions taken in conjunction with the accompanying drawings, in which like reference characters refer to the same parts throughout the different views, in which;

FIG. 1 is a circuit diagram of a memory cell having a diode structure according to conventional art;

FIG. 2 is a circuit diagram illustrating an equivalent circuit of a semiconductor memory device according to an exemplary embodiment of the present invention;

FIG. 3 is a sectional view illustrating a memory cell and a word line contact used in the device shown in FIG. 2;

FIG. 4 illustrates one example of a layout structure for memory cells and word line contacts used in the device shown in FIG. 2;

FIG. 5 illustrates an occurrence of the bridge effect, such as a short-circuit in FIG. 4; and

FIG. 6 illustrates an exemplary embodiment of a layout structure for the memory cells and word line contacts shown in FIG. 2.

### DETAILED DESCRIPTION OF EXEMPLARY EMBODIMENTS

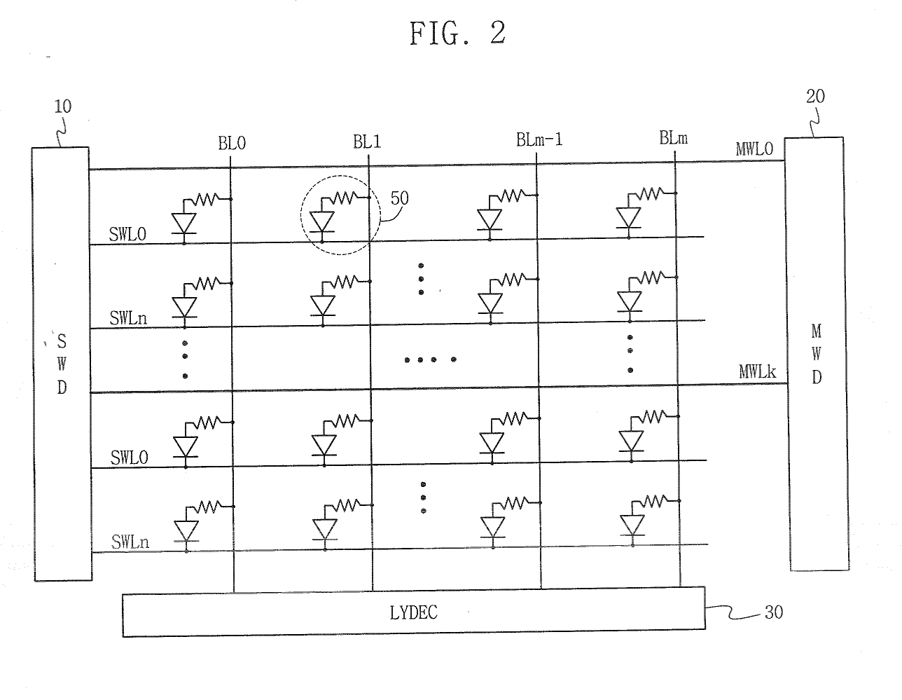

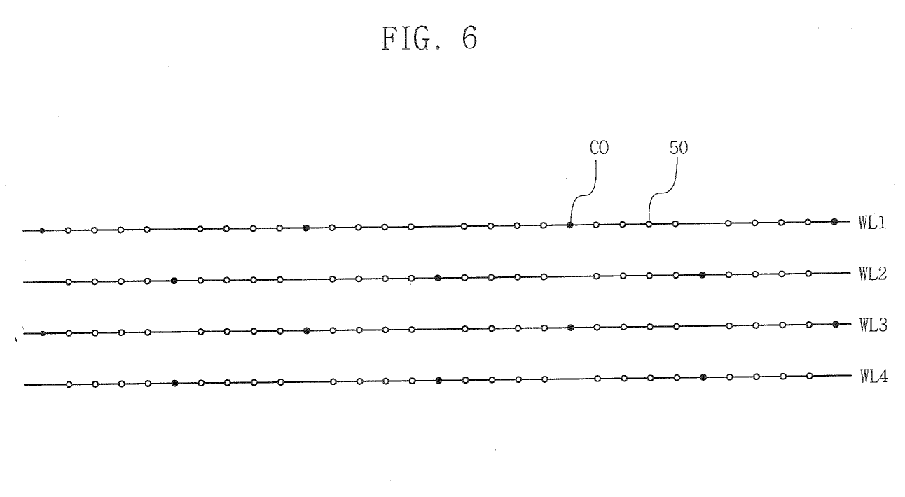

Exemplary embodiments of the present invention now will be described more fully hereinafter with reference to FIGS. 2 and 6. This invention may, however, be embodied in many different forms and should not be construed as limited to the exemplary embodiments set forth herein. Rather these exemplary embodiments are provided so that this disclosure will be thorough and complete, and will fully convey the scope of the invention to those skilled in the art.

FIG. 2 schematically illustrates a semiconductor memory device having a diode structure according to an exemplary embodiment of the present invention.

As shown in FIG. 2, a semiconductor memory device according to an exemplary embodiment of the present invention includes memory cells, one of which is shown by the dashed circle 50, bit lines BL0 through BLm (m being a natural number greater than or equal to 1), main word lines MWL0 through MWLk (k being a natural number greater than or equal to 1), sub word lines SWL0 through SWLn (n being a natural number greater than or equal to 1), a main word line driver MWD 20, a sub word line driver SWD 10, and a local column decoder LYDEC 30.

The semiconductor memory device may a multi-bank or multi-mat structure well-known to those of ordinary skill in the art.

The main word line driver 20 may be a main decoder or global row decoder. The sub word line driver 10 may be a sub row decoder or local row decoder. The local column decoder 30 may be referred to as a sob column decoder.

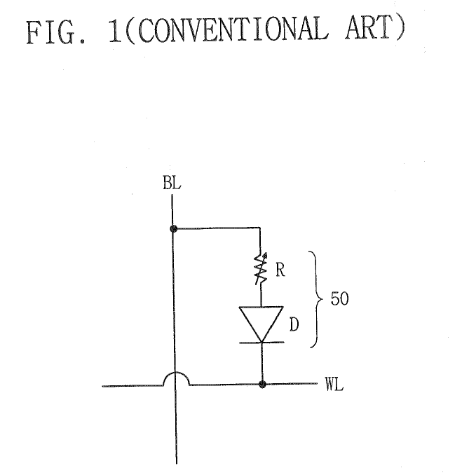

The memory cells 50 each have a diode structure, as shown in FIG. 1. Each of the memory cells 50 is directly coupled to any one of bit lines BL as a column line, and is directly coupled to any one of the sub word lines SWT as a row line. The memory cells 50 are selected by enabled bit lines BL and sub word lines SWT, each being coupled to the memory cells 50. For example, when a first bit line BL1 and a 0^{th} sub word line SWL0 are enabled, the memory cell 50 shown in the drawing is selected.

The main word line driver 20 performs control so that any one of the main word lines MWL0 through MWLk is enabled in response to a row address signal from the outside thereof.

The sub word line driver 10 controls the enabling of any one sub-word line SWLi of the sub word lines SWL0 through SWLn in response to an enable signal of the enabled main word line and an address signal, when any one of the main word lines MWL0 through MWLn is enabled. For example, when the 0^{th} main word line MWL0 is enabled, any one of a plurality of sub word lines SWL0 through SWLn shown in an upper part of the drawing is enabled.

The local column decoder 30 performs control in response to a column address signal, so that any one of the bit lines BL0 through BLm that are individually coupled with the plurality of memory cells 50 is selected. Thus, a transmission of data is controlled in a read or write operation. When necessary, a global bit line (not shown) may be further disposed and a global column decoder (not shown) may be disposed.

An internal sectional layout structure in a semiconductor memory device having the structure described above according to an exemplary embodiment of the invention will, be described as follows.

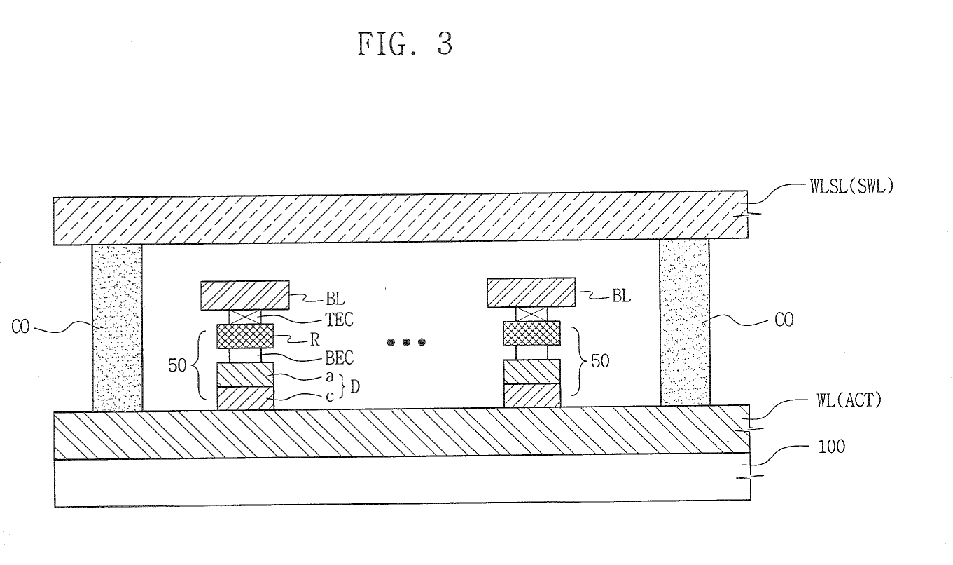

FIG. 3 illustrates a layout structure of memory cells and a word line contact coupled on one sub word line, according to an exemplary embodiment of the present invention.

With reference to FIG. 3, an active region WL (ACT) is disposed on a semiconductor substrate 100. The active region WL (ACT) has a first direction as a length direction and a second direction as a width direction intersected with the first direction.

As well known to those of ordinary skill in the art, a plurality of active regions ACT adjacent in the second direction are disposed to configure a semiconductor memory device like in FIG. 2.

The active region WL (ACT) is formed being doped with an impurity, for example, an N-type impurity, of high density.

A plurality of memory cells 50 are respectively disposed on the active regions WL (ACT). The plurality of memory cells 50 are disposed being distanced by a given interval in the first direction on the active region WL (ACT). More specifically, in the first direction, at least one each of contacts CO is disposed for each predetermined number of memory cells 50. This will be described as follows.

Each of the memory cells 50 has a structure of one diode D and a variable resistance device R coupled to each other. For example, on the active region WL (ACT), a cathode region c of the diode D, and an anode region a formed on the cathode region c, are disposed perpendicularly to the semiconductor substrate 100. The diode D may be formed through a selective epitaxial growth (SEG) in the layout.

A bottom electrode contact BEC for electrically connecting the diode D to the variable resistance device R is disposed on the diode D, and the variable resistance device R formed of a phase change material or a transition metal oxide is disposed on the contact BEC.

Wiring layers for a layout of signal lines are formed on the memory cells 50.

Bit lines BL are formed in the lowest layer of the wiring layers. The bit lines BL are disposed corresponding to the number of memory cells disposed on the active region WL (ACT).

The bit lines BL are each coupled with the variable resistance device R constituting each of the memory cells 50 through each top electrode contact TEC. The bit lines BL are arrayed with a given interval in a second direction as a length direction intersected with the first direction. The bit lines BL have a direction intersected with the length direction of the active regions WL (ACT), as its length direction, and are coupled with memory cells 50 overlapped in the second direction as the length direction of the bit lines BL, through a contact TEC, in a perpendicular direction to the semiconductor substrate 100.

A sub word line WLSL (SWL) is formed on a wiring layer on which the bit line BL is wired.

The sub word line WLSL (SWL) is disposed in the first direction as a length direction. The sub word line WLSL (SWL) may have, as a length direction, the same direction as the length direction of the active region WL (ACT), and may be disposed to overlap with the memory cells 50 in a direction perpendicular to the semiconductor substrate 100.

The sub word line WLSL (SWL) is disposed to obtain a high speed, because resistance of the active region WL (ACT) as a word line is relatively large. For clarity, the active region WL (ACT) will be mentioned as a word line WL, and the sub word line WLSL (SWC) will be mentioned as a word line strapping line WLSL in the following description.

A layout of the word line contacts CO connecting the word line strapping line WLSL with the word line WL may be different according to a magnitude of the resistance of the word line WL, and may be also different according to the tendency to higher integration.

At least one each of the word line contacts CO may be disposed in predetermined numbers of memory cells disposed on the word line WL. For example, eight memory cells are disposed and then the word line contact may be disposed on a ninth memory cell region. On the other hand, four memory cells are disposed and then the word line contact may be fanned an a fifth memory cell region.

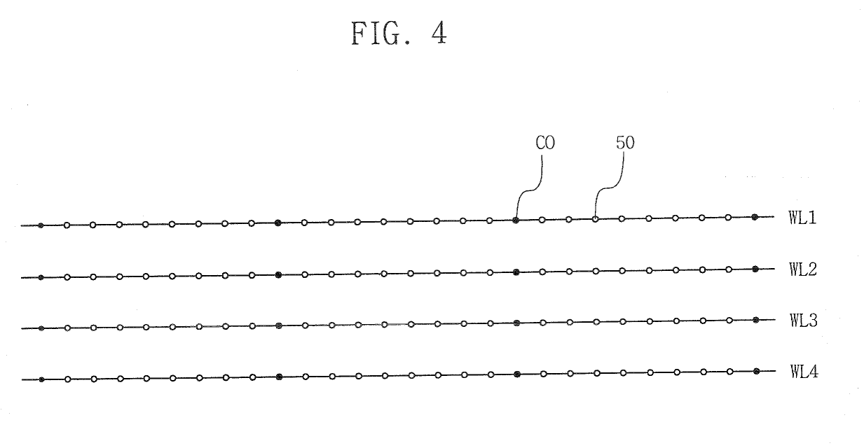

FIG. 4 illustrates one example of a layout structure of the word line contacts CO shown in FIG. 3.

As shown in FIG. 4, it is assumed that four word lines WL1, WL2, WL3 and WL4 are disposed in a first direction as a length direction, open circles in the drawing indicate the memory cells 50 and solid circles indicate the word line contacts CO.

The word lines WL1, WL2, WL3 and WL4 are disposed adjacent to one another in the second direction.

The memory cells 50 and the word line contacts CO are disposed on the respective word lines WL1, WL2, WL3 and WL4.

The word line contacts CO disposed on any one, for example, the first word line WL1, of the word lines WL1, WL2, WL3 and WL4, have a structure such that each one is disposed every predetermined numbers of successive memory cells 50. FIG. 4 illustrates an example in which one of the word line contacts is disposed every eight memory cells 50. On the remaining word lines WL2, WL3 and WL4 of the word lines WL1, WL2, WL3 and WL4, the word line contacts CO and memory cells 50 are disposed in the same layout structure as the first word line WL1.

The layout structure shown in FIG. 4 may be advantageous for a high integration circuit level. If a resistance magnitude of the word line or several process conditions are satisfied, more memory cells may be provided as one unit, thereby reducing an area of a word line contact CO.

That is, the word line contacts CO are disposed adjacent in the second direction to word line contacts CO disposed in adjacent word lines, and the number of word line contacts CO disposed on one word line WL can be reduced and memory cells are disposed in a remaining region, thereby realizing a high level of circuit integration.

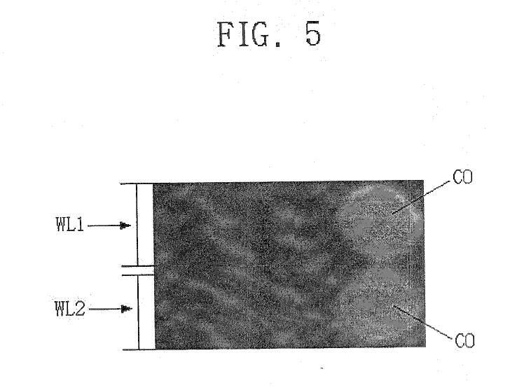

In such a layout structure, when the semiconductor memory device is becoming more integrated, a problem may be caused. As shown in FIG. 5, in the case where two word lines WL1 and WL2 are adjacent each other and the word line contacts CO disposed on the word lines WL1 and WL2 are adjacent in the second direction, a bridge effect, such as a short-circuit of the word lines contacts CO becoming in contact with each other, may occur. In case the bridge effect such as a short-circuit is generated, for example, despite trying to select a first word line WL1, a second word line WL2 may be selected in the operation of the semiconductor memory device. In this case, there is a need to make the layout of the word line contacts different from the existing layout, which will be described with reference to FIG. 6.

FIG. 6 illustrates an exemplary embodiment for the layout structure of the word line contacts CO shown in FIG. 3.

As shown in FIG. 6, it is assumed that four word lines WL1, WL2, WL3 and WL4 are disposed in a first direction as a length direction, open circles in the drawing indicate the memory cells 50 and solid circles indicate the word line contacts CO.

The word lines WL1, WL2, WL3 and WL4 are disposed adjacent one another in the second direction. Memory cells 50 and word line contacts CO are disposed on the respective word lines WL1, WL2, WL3 and WL4.

Word line contacts CO disposed on any one, for example, the first word line WL1, of the word lines WL1, WL2, WL3 and WL4, have a structure that each one is disposed every predetermined numbers of memory cells 50. In FIG. 6, one of the word line contacts CO is disposed every eight memory cells 50.

Memory cells 50 and word line contacts CO on the second word line WL2 adjacent to the first word line WL1 have a little different layout structure from the layout on the first word line WL1 but have the same pitch. Word line contacts CO of the second word line WL2 are disposed so as not to be adjacent the word line contacts CO of the first word line WL1.

More specifically, the word line contacts CO disposed on one word line, for example, WL2, are disposed in staggered relationship, so as not to be adjacent in the second direction to word line contacts CO that are disposed on adjacent word lines, for example, WL1 and WL3, adjacent the one word line in the second direction intersected with the first direction. A word line contact CO disposed on the word line WL1 or WL3 adjacent in the second direction to the one word line contact CO disposed on the word line WL2, may be disposed on the word line WL1 or WL3 at a position passing in the first direction by at least one memory cell (50) region from a position adjacent to the one word line contact. For example, the word line contact CO may be disposed after passing by four memory cell regions.

In an example, in sequentially disposing first through nth word lines in the second direction, memory cells 50 and word line contacts CO are disposed on odd-number lines with the same structure. Memory cells 50 and word line contacts CO may be disposed on even-number lines so that word line contacts CO disposed on the even-number word lines are not adjacent in the second direction to word line contacts CO disposed on the odd-number word lines.

Such layout structure described above can prevent or substantially reduce defects, such as a bridge effect of a short-circuit in adjacent word line contacts.

Though exemplary embodiments of the present invention were described above, being applied only to PRAM or RRAM, the layout structure of the invention may be applied to other semiconductor memory devices including an MRAM, a FRAM (Ferroelectric Random Access Memory), a DRAM, or other volatile or nonvolatile memories through modifications or variations, in a cell structure having the same as, or similar to, the above-described memory cell structure.

It will be apparent to those of ordinary skill in the art that modifications and variations can be made in the present invention without deviating from the spirit or scope of the invention. Thus, it is intended that the present invention cover any such modifications and variations of this invention provided they come within the scope of the appended claims and their equivalents. Accordingly, these and other changes and modifications are seen to be within the true spirit and scope of the invention as defined by the appended claims.

In the drawings and specification, there have been disclosed exemplary embodiments of the present invention and, although specific terms are employed, they are used in a generic and descriptive sense only and not for purposes of limitation, the scope of the invention being set forth in the following claims.

What is claimed is:

1. A semiconductor memory device comprising:
an active region extending in a first direction on a semiconductor substrate and serving as a word line;
a plurality of memory cells disposed on the active region and each having one variable resistance device and one diode device; and
a plurality of word line contacts, at least one of the word line contacts being disposed every predetermined number of successive memory cells.

2. The device of claim 1, wherein the word line contacts are electrically connected to a plurality of word line strapping lines that are disposed over the memory cells and extend in the first direction.

3. The device of claim 2, wherein word line contacts disposed on one active region are not adjacent in a second direction intersecting the first direction to word line contacts disposed on another active region adjacent in the second direction to the one active region.

4. The device of claim 3, wherein the positions of the word line contacts on the one active region are deviated from the positions of portions of the one active region, adjacent to the word line contacts on the adjacent active region, by at least one memory cell region.

5. The device of claim 4, wherein a cathode region of the diode device constituting the memory cell is coupled to the active region, and an anode region of the diode device is coupled to the variable resistance device.

6. The device of claim 5, wherein at least one of the word line contacts is disposed every eight or four successive memory cells.

7. The device of claim 6, wherein the semiconductor memory device comprises a PRAM (Phase change Random Access Memory) in which the variable resistance device is formed of phase change material GST (GeₓSb_{y}Teₓ).

8. The device of claim 6, wherein the semiconductor memory device comprises an RRAM (Resistance Random Access Memory) in which the variable resistance device is formed of a transition metal oxide.

9. A word line layout structure in a semiconductor memory device which comprises a plurality of active regions extending in a first direction and serving as word lines, a plurality of word line strapping lines, a plurality of memory cells disposed on the active regions, and a plurality of word line contacts disposed on the active regions and electrically connecting the active regions to the word line strapping lines,
wherein at least one of the word line contacts is provided every predetermined number of successive memory cells on each of the active regions and the word line contacts disposed on one active region are not adjacent in a second direction intersecting the first direction to the word line contacts disposed on another active region adjacent in the second direction to the one active region.

10. The structure of claim 9, wherein the positions of the word line contacts on the one active region are deviated from the positions of portions of the one active region, adjacent to the word line contacts on the adjacent active region, by at least one memory cell region.

11. The structure of claim 10, wherein each memory cell comprises one variable resistance device and one diode device.

12. The structure of claim 11, wherein a cathode region of the diode device constituting the memory cell is coupled to the active region, and an anode region of the diode device is coupled to the variable resistance device disposed on the diode device.

13. The structure of claim 12, wherein at least one of the word line contacts is disposed every eight or four successive memory cells.

14. The structure of claim 13, wherein the semiconductor memory device comprises a PRAM in which the variable resistance device is formed of phase change material GST.

15. The structure of claim 13, wherein the semiconductor memory device comprises an RRAM in which the variable resistance device is formed of a transition metal oxide.
